(19) United States
(12) Patent Application Publication
(10) Pub. No.: US 2009/0140783 A1
(43) Pub. Date: Jun. 4, 2009

(54) SEMICONDUCTOR DEVICE

(75) Inventor: Toru ISHIKAWA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/325,092

(22) Filed: Nov. 28, 2008

(30) Foreign Application Priority Data
Nov. 29, 2007 (JP) 2007-308986

(51) Int. Cl. H03H 11/26

(52) U.S. Cl. 327/158; 327/277

(57) ABSTRACT

Disclosed is a semiconductor device having a delay adjusting circuit including a delay line having N stages of differential delay circuits and N stages of differential interpolators. A differential interpolator of an Mth (where M<N holds) stage receives an output signal of a differential delay circuit of the Mth stage and an output signal of a differential interpolator of an (M+1)th stage. A differential amplifier of an Nth stage receives an output signal of a differential delay circuit of the Nth stage as an input and synthesizes this signal into a signal with a synthesizing ratio of 100%. One differential interpolator from among differential interpolators from first to (N−1)th stages performs waveform synthesis over a range of 0% to 100% in accordance with an analog control signal from a digital-to-analog converter. The output of the differential interpolator of the first stage becomes an output signal, the delay of which has been adjusted.

### REFERENCE TO RELATED APPLICATION

This application is based upon and claims the benefit of the priority of Japanese patent application No. 2007-308986 filed on Nov. 29, 2007, the disclosure of which is incorporated herein in its entirety by reference thereto.

1. Field of the Invention

This invention relates to a semiconductor device and, more particularly, to a semiconductor device having a delay adjusting circuit suited for application in a DLL (Delay-Locked Loop).

2. Description of the Related Art

A delay adjusting circuit such as a DLL for adjusting the delay of an internal clock signal is in wide spread use in a system in which high-speed data transfer is carried out. A basic circuit of a delay adjusting circuit is one that adjusts delay depending upon voltage level, such as a VCDL (Voltage-Controlled Delay Line). In case of operation only at a specific frequency, the VCDL is designed in accordance with the specific frequency. However, in a DDR (Double Data Rate) 2—DRAM (Dynamic Random-Access Memory), for example, operation at 2 ns on the high-speed side and 8 ns on the low-speed side is required in terms of the clock period (tCK). Operation that covers a broad range of frequencies and that is stable is required.

FIG. 9A is a diagram illustrating an example of the configuration of a DLL according to the related art (see Non-Patent Document 1). The DLL includes a VCDL 20 having a plurality of differential delay circuits (differential amplifying circuits) and adapted to vary delay time by bias voltage. A differential amplifying circuit (buffer) 30 that is the last stage receives a differential output signal of the preceding stage and delivers a single-ended output. The DLL further includes a phase detector (phase comparator) 60 for detecting the phase difference between the input and output; a phase adjusting counter 50 for receiving the result from the phase detector 60, and being counted up or down in accordance with the phase difference between the input and output; and a D/A converter 40 for receiving the count value from the phase adjusting counter 50, converting the count to an analog signal and supplying the VCDL 20 with a bias voltage. FIGS. 9B and 9C are diagrams illustrating the configuration of three stages of differential delay circuits constructing the VCDL 20 of FIG. 9A.

As shown in FIG. 9C, each differential delay circuit has a differential pair comprising N-channel MOS transistors N1 and N2 having sources commonly coupled and drains connected to a power supply via load elements L1 and L2, respectively. The commonly coupled sources of the differential pair is connected to the drain of a current-source transistor N3 having a gate to which a bias voltage Vbias is applied. The drains of the differential pair of the preceding stage are connected to the respective gates of the succeeding differential pair. The arrangement shown in FIGS. 9A to 9C adjusts the delay level of the differential amplifying circuit to thereby vary the delay of the VCDL itself.

[Non-Patent Document 1] R. Jacob Baker, “CMOS”, Second Edition, WILEY INTERSCIENCE, 2005, p. 598

### SUMMARY OF THE DISCLOSURE

The following analysis is given by the present invention. In the arrangement shown in FIGS. 9A to 9C, the range of delay control of one differential delay circuit (differential amplifying circuit) is limited, and the overall adjustment range of the VCDL also is limited by this range of adjustment.

Increasing the delay amount of the differential delay circuit (differential amplifying circuit) constituting the VCDL lowers the signal slew rate. In this case, noise immunity deteriorates.

The present invention seeks to solve the one or more of the above problems.

According to the present invention, there is provided a semiconductor device having a delay adjusting circuit comprising: a delay line (a delay-circuit row) comprising a plurality of stages of delay circuits in which a signal received by a first stage propagates in a direction of from a preceding stage to a succeeding stage in the delay line; and a plurality of stages of interpolators arranged in such a manner that a signal propagates in a direction that is the reverse to the direction of signal propagation in the delay line. At least one interpolator among the plurality of stages of interpolators receives a signal from the delay circuit of the corresponding stage and a signal output from the interpolator of the succeeding stage, performs waveforms synthesis of the signals received with a ratio specified by a control signal supplied thereto and outputs the synthesized signal to a preceding stage. The synthesized signal produced from an interpolator situated at a first stage is used as a delay-adjusted signal. An interpolator situated at a last stage receives an output from the delay circuit of the stage corresponding to the interpolator of the last stage.

In one embodiment of the present invention, each delay circuit of the delay-circuit row includes a differential delay circuit for differentially receiving an input signal and differentially outputting an output signal.

In one embodiment of the present invention, the one interpolator includes first and second differential amplifying circuits having respective output pairs connected to a common load element pair, and outputting differentially an output signal from connection nodes of the output pairs and the common load-element pair. The first differential amplifying circuit differentially receives an output signal of the delay circuit. The second differential amplifying circuit differentially receives an output signal of the interpolator of the succeeding stage. The first and second differential amplifying circuits receive the control signals, respectively, vary driving currents respectively to vary the delayed output.

In one embodiment of the present invention, the interpolator of the last stage includes a first differential amplifying circuit for differentially receiving differentially an output signal from the delay circuit of the stage corresponding to the interpolator of the last stage.

In one embodiment of the present invention, the first differential amplifying circuit includes a first differential pair having an output pair connected to the load element pair, and a first current source that supplies a driving current to the first differential pair. The second differential amplifying circuit includes a second differential pair having an output pair connected to the common load element pair, and a second current source that supplies the second differential pair with a driving current. A first bias voltage for controlling the current value of the first current source is supplied to the first current source as the control signal, and a second bias voltage for controlling the current value of the second current source is supplied to the second current source as the control signal.

In one embodiment of the present invention, the first differential amplifying circuit includes a first differential pair having an output pair connected to the common load element pair, a first current source for supplying a driving current to the first differential pair, and a first switch for turning a current path of the first current source on and off. The second differential amplifying circuit includes a second differential pair having an output pair connected to the common load element pair, a second current source for supplying a driving current to the second differential pair and a second switch for turning a current path of the second current source on and off. A first bias voltage for controlling the current value of the first current source is supplied to the first current source as the control signal, and a second bias voltage for controlling the current value of the second current source is supplied to the second current source as the control signals.

In one embodiment of the present invention, the differential delay circuit includes a differential pair for differentially receiving an output signal from the preceding stage at an input pair and outputting an output signal differentially from an output pair; a load element pair connected to the output pair; and a current source for supplying the differential pair with a driving current.

In another embodiment of the present invention, the differential delay circuit includes a differential pair for differentially receiving an output signal from the preceding stage at an input pair and differentially outputting an output signal from an output pair, a load element pair connected to the output pair; a current source for supplying the differential pair with a driving current; and a switch for turning a current path of the current source on and off.

In one embodiment of the present invention, the delay adjusting circuit further comprises a phase detector for detecting a phase difference between an output signal from the interpolator of the last stage and the input signal; a counter, which receives an output of the phase detector as an input, for being counted up or down in accordance with phase lag or phase lead; a digital-to-analog converter, which receives a bit signal of a first bit field of the count output from the counter as a digital input, for outputting an analog voltage; and a selector for selecting any interpolator of the plurality of stages based upon a bit signal of a second bit field of the count output from the counter, supplying the analog voltage from the digital-to-analog converter to the selected interpolator as the control signal, and supplying the other interpolators with previously prepared analog voltages as the control signal.

In one embodiment of the present invention comprises a delay line having N stages of differential delay circuits, and N stages of differential interpolators; wherein a differential interpolator of an Mth (where M<N holds) stage receives an output signal of a differential delay circuit of the Mth stage and an output signal of a differential interpolator of an (M+1)th stage; a differential amplifier of an Nth stage receives an output signal of a differential delay circuit of the Nth stage as an input and synthesizes this signal into a signal with a synthesizing (interpolation) ratio of 100%; a selected differential interpolator from among differential interpolators from first to (N−1)th stages performs waveform synthesis of the signals received with a ratio of a range of 0% to 100% in accordance with an analog signal from a digital-to-analog converter; and a delay-adjusted output signal is output from the differential interpolator of the first stage.

In the present invention, differential delay circuits and differential interpolators from the (M+2)th stage onward are set to the inactive state during delay adjustment by the differential interpolator of the Mth stage.

A delay adjusting circuit according to the present invention comprises a delay line having N stages of differential delay circuits, and differential interpolators of L (where N>L>1 holds) stages; wherein differential delay circuits of N stages are divided into L-number of groups; an output of one differential delay circuit among differential delay circuits of an Mth (where M<N holds) group and an output of a differential interpolator of an (M+1)th stage are supplied to a differential interpolator of an Mth stage; a differential interpolator of an Lth stage receives an output of one differential delay circuit among differential delay circuits of an Lth group as an input and synthesizes this signal into a waveform with a synthesizing ratio of 100%; and a delay-adjusted output signal is output from the differential interpolator of the first stage.

In accordance with the present invention, the range of a delay adjustment can be expanded from a delay time equivalent to one stage of a delay circuit and one stage interpolator to a synthesized delay time equivalent to a plurality of stages of delay circuits and a plurality of stages of interpolators.

Further, in accordance with the present invention, even if delay time is lengthened, a situation in which the slew rate of a delay circuit is lengthened and resistance to noise deteriorates is avoided.

Still other features and advantages of the present invention will become readily apparent to those skilled in this art from the following detailed description in conjunction with the accompanying drawings wherein only the preferred embodiments of the invention are shown and described, simply by way of illustration of the best mode contemplated of carrying out this invention. As will be realized, the invention is capable of other and different embodiments, and its several details are capable of modifications in various obvious respects, all without departing from the invention. Accordingly, the drawing and description are to be regarded as illustrative in nature, and not as restrictive.

### BRIEF DESCRIPTION OF THE DRAWING

FIG. 1 is a diagram illustrating the configuration of an exemplary embodiment of the present invention;

FIG. 2 is a diagram illustrating the configuration of an exemplary embodiment of the present invention;

FIG. 3 is a diagram useful in describing the operation of an exemplary embodiment of the present invention;

FIG. 4A to 4C are a diagram useful in describing the operation of an exemplary embodiment of the present invention;

FIG. 5A and 5B are a diagram useful in describing the operation of an exemplary embodiment of the present invention;

FIG. 6A and 6B are a diagram useful in describing the operation of an exemplary embodiment of the present invention;

FIG. 7 is a diagram illustrating the configuration of another exemplary embodiment of the present invention;

FIG. 8 is a diagram illustrating the configuration of another exemplary embodiment of the present invention; and

FIG. 9A to 9C are a diagram illustrating the configuration of the related art.

### PREFERRED MODES OF THE INVENTION

Exemplary embodiments of the present invention will be described in detail with reference to the drawings. The present invention provides a delay adjusting circuit including: a delay-circuit row (delay line) comprising a plurality of stages of delay circuits (1-1, 2-1, 3-1, 4-1, 5-1), and a plurality of stages of interpolators (11, 12, 13, 14, 15), which are arranged in such a manner that signal propagation is in a direction that is opposite to the direction of propagation of the signal in the delay line, for interpolating received signals and outputting a interpolated signal. One interpolator (e.g., 11) receives a signal from the delay circuit (1-1) of the stage corresponding to this one interpolator (11) and a signal that is output from the interpolator (12) of the succeeding stage, synthesizes the waveforms of the received signals based upon control signals (a1, a1b, a2, a2b . . . ) and outputs the synthesized signal; and a delay-adjusted signal is output from the interpolator (11) of the first stage. A signal from the delay circuit (5-1) of the stage corresponding to the interpolator (15) of the last stage is supplied to the interpolator (15) of the last stage. In the present invention, the interpolators of the plurality of stages may be provided in correspondence with respective ones of the delay circuits of the plurality of stages or they may be reduced in number (i.e., the number of stages thereof may be less than the number of stages of the delay circuits). In the present invention, each delay circuit includes a differential delay circuit for differentially receiving an input signal and differentially outputting an output signal.

In the present invention, one interpolator (e.g., 11) includes first and second differential amplifying circuits (1-2, 1-3), in which output pairs are commonly connected and connected to a load element pair, for outputting an output signal differentially from connection nodes of the output pair and load-element pair. The first differential amplifying circuit (1-2) differentially receives an output signal of the delay circuit (1-1), the second differential amplifying circuit (1-3) differentially receives a differential output signal of the interpolator (12) of the succeeding stage, and the first and second differential amplifying circuits (1-2, 1-3) receive the control signals (a1, a1b), and (a2, a2b), respectively, and vary driving currents respectively to vary the delay of the differential output signal.

In the present invention, the interpolator (15) has only a first differential amplifying circuit (5-2) for differentially receiving a differential signal from the delay circuit (5-1) of the stage corresponding to this interpolator (15).

In the present invention, the delay adjusting circuit further includes a phase detector (9) for detecting a phase difference between an output signal (OUT) from the interpolator (11) and an input signal (IN) supplied to the first stage of the delay line; a counter (8), which receives an output of the phase detector (9) as an input, for being counted up and down in accordance with phase lag and lead; a digital-to-analog converter (7), which receives a bit-signal group (e.g., lower order bits) of a first bit field of the count output of the counter (8) as a digital input, for outputting an analog voltage; and a selector (6) for selecting an interpolator based upon a bit-signal group (e.g., upper order bits) of a second bit field of the count output of the counter, supplying a level signal from the digital-to-analog converter (7) to the selected interpolator, and supplying the other interpolators with a fixed value as the control signal. When one interpolator is selected by the selector (6) and the output voltage of the digital-to-analog converter (7) is supplied as the control signal of this one differential interpolator, the other differential interpolators are supplied with a control signal of a fixed potential for performing waveform synthesis of either an output of the delay circuit or an output of the preceding-stage interpolator with a synthesizing ratio of 100%.

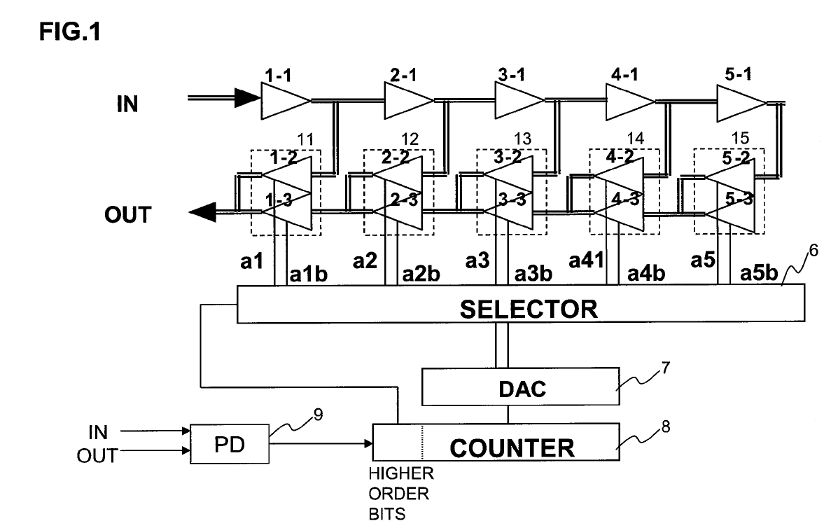

FIG. 1 is a diagram illustrating the configuration of one exemplary embodiment of the present invention. The delay adjusting circuit according to this exemplary embodiment includes differential delay circuits 1-1, 2-1, 3-1, 4-1 and 5-1 of N stages (N=5 holds in FIG. 1); differential interpolators 11, 12, 13, 14 and 15 of N stages; a selector 6; a digital-to-analog converter (DAC) 7; a counter (phase adjusting counter) 8; and a phase detector (PD) 9. An input IN is applied to the differential delay circuit 1-1 of the first stage and propagates through the differential delay circuits 1-1, 2-1, 3-1, 4-1 and 5-1.

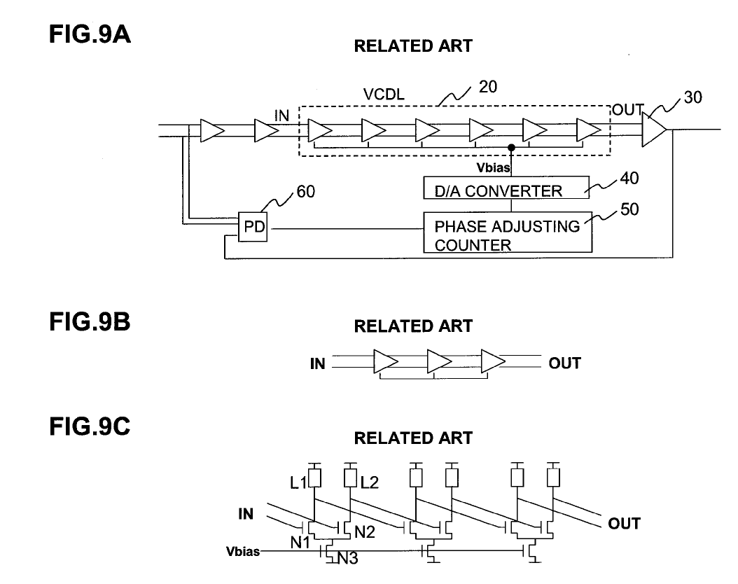

In FIG. 1, the digital-to-analog converter (DAC) 7, counter (phase adjusting counter) 8 and phase detector (PD) 9 are identical with the D/A converter 40, phase adjusting counter 50 and phase detector (PD) 60, respectively, shown in FIG. 9. As will be described below, the selector 6 is added on. The upper order bits of the counter 8 are supplied to the selector 6, and the lower order bits of the counter 8 are supplied to the digital input signal of the DAC 7. The differential interpolator selected by the selector 6 receives the analog signal from the DAC 7 and signals of the reverse phase (a1, a1b, etc.). The phase detector 9 detects the phase difference between the input signal IN and output signal OUT. It may be so arranged that the phase detector 9 compares phases of signals obtained by a single-ended conversion rather than a differential conversion. It should be noted that in a case where one of the differential interpolators 11, 12, 13, 14 and 15 of the five stages is selected in FIG. 1, the three upper order bits of the count output of counter 8 are supplied to the selector 6 and the lower order bits, i.e., lower bits other than the three upper order bits, of the count output of counter 8 are supplied to the DAC 7, although this does not impose any particular limitation.

Each of the differential delay circuits 1-1, 2-1, 3-1, 4-1 and 5-1 comprises a differential amplifying circuit having a differential pair which have coupled sources connected to a current source, gates connected respectively to drains of differential-pair transistors of the preceding stage and drains connected to a power supply via load elements. The direction of signal propagation in the differential interpolators 11, 12, 13, 14 and 15 of the N stages is opposite to the direction of signal propagation in the differential delay circuits 1-1, 2-1, 3-1, 4-1 and 5-1 and the delay-adjusted output signal OUT is output from the differential interpolator 11 of the first stage. That is, the differential interpolator 11, which is the first stage in terms of placement, is the last stage in terms of signal propagation which outputs the delay-adjusted output signal.

The differential interpolator 11 has two differential amplifying circuits 1-1 and 1-3 which have output pairs (drains) commonly connected to a common load element pair. The differential amplifying circuits 1-2 and 1-3 differentially receive a differential output signal of the differential delay circuit 1-1 and a differential output signal of the differential interpolator 12, respectively, vary the delay in accordance with bias voltages a1 and a1b of respective current-source transistors and differentially output a synthesized signal. The bias voltages a1 and a1b are differentially supplied from the DAC 7 via the selector 6 (a1=VCM+ΔV/2, a1b=VCM−ΔV/2, where ΔV=a1−a1b holds and VCM is a common-mode voltage), although this does not impose any particular limitation to the present invention.

The differential interpolator 12 has a configuration identical with that of the differential interpolator 11 and includes two differential amplifying circuits 2-2 and 2-3 in which output pairs are commonly connected to a common load element pair. The differential amplifying circuits 2-2 and 2-3 differentially receive a differential output signal of the differential delay circuit 2-1 and a differential output signal of the differential interpolator 13, respectively, vary the delay in accordance with bias voltages a2 and a2b of respective current-source transistors, differentially output a synthesized signal and differentially supply the signal to the differential amplifying circuit 1-3 of the differential interpolator 11. The bias voltages a2 and a2b are differentially supplied from the DAC 7 via the selector 6 (a2=VCM+ΔV/2, a2b=VCM−ΔV/2, wherein ΔV=a2 and a2b holds and VCM is a common-mode voltage), although this does not impose any particular limitation to the present invention.

The differential interpolator 15 has two differential amplifying circuits 5-2 and 5-3 in which output pairs are commonly connected to a common load element pair. The differential amplifying circuit 5-2 differentially receives a differential output signal of the differential delay circuit 5-1, varies the delay in accordance with bias voltage a5 of a current-source transistor and differentially supplies a differential output to the differential amplifying circuit 4-3 of the differential interpolator 14. The differential interpolator 15 receives the signal from the differential delay circuit 5-1 as an input and performs waveform synthesis using this signal as 100%. The differential amplifying circuit 5-3 is not used. The bias voltages a5 and a5b are differentially supplied from the DAC 7 via the selector 6 (a5=VCM+ΔV/2, a5b=VCM−ΔV/2, wherein ΔV=a5−a2b holds and VCM is a common-mode voltage). In this case, a5 is a voltage of 100% and a5b is a voltage of 0%.

Only one differential interpolator selected by the selector 6 from among the differential interpolators 11 to 14 of the first to fourth stages performs waveform synthesis over a range of 0 to 100% in accordance with the analog voltage signal from the DAC 7.

For example, with regard to one differential interpolator 11 selected by the selector 6, if the analog voltage signal of the DAC 7 has reached, e.g., 100%, then the selector 6 changes over in such a manner that fixed potentials of 100% and 0% are applied, as the potentials of a1 and a1b, to the selected differential interpolator 11. These potentials are supplied as the potentials of a1 and a1b to the differential interpolator 11 also in a case where the differential interpolator 11 is not selected by the selector 6.

The output of the differential interpolator 11 of the first stage is a delay signal, delay of which has been adjusted by the DLL. The counter 8 corresponds to the phase adjusting counter 50 of FIG. 9. The count value from the counter 8 is supplied to the DAC 7. In addition, the counter 8 selects the selector 6.

In a case where the delay is short in the 5-stage delay adjusting circuit of FIG. 1, the shortest is the delay (2-unit delay) of the differential delay circuit 1-1 and differential amplifying circuit 1-2, and the maximum delay is the delay of the differential delay circuits 1-1, 2-1, 3-1, 4-1 and 5-1 and differential amplifying circuits 5-2, 4-3, 3-3, 2-3 and 1-3 of the differential interpolators 15, 14, 13, 12 and 11, respectively.

The maximum value of the delay adjustment range is capable of being set at will if the number of differential delay circuits and differential interpolators is increased. The minimum value of the delay adjustment range is that afforded by two differential amplifying circuits. That is, a delay smaller than that of the arrangement of FIG. 9 is supportable.

Further, since the delays of the differential amplifying circuits per se are not changed, the slew rate of the signal of the differential amplifying circuits does not become slow and noise immunity does not deteriorate.

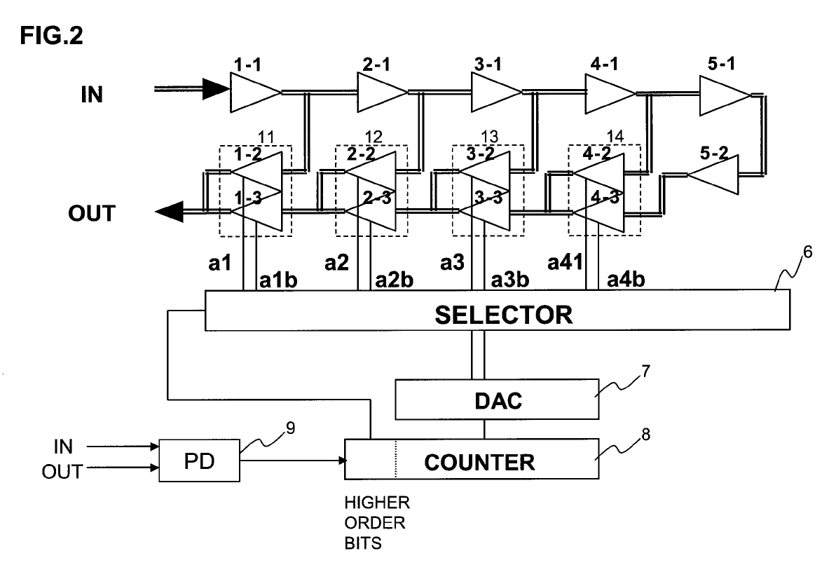

The arrangement shown in FIG. 1 is essentially equivalent to the arrangement shown in FIG. 2. In this case, the differential interpolators 11, 12, 13 and 14 of the first to fourth stages are capable of performing waveform synthesis (delay synthesis) of the received signals. In this exemplary embodiment, however, the differential interpolator that performs signal delay synthesis is only one differential interpolator selected by the selector 6 from among the differential interpolators 11, 12, 13 and 14 of the four stages.

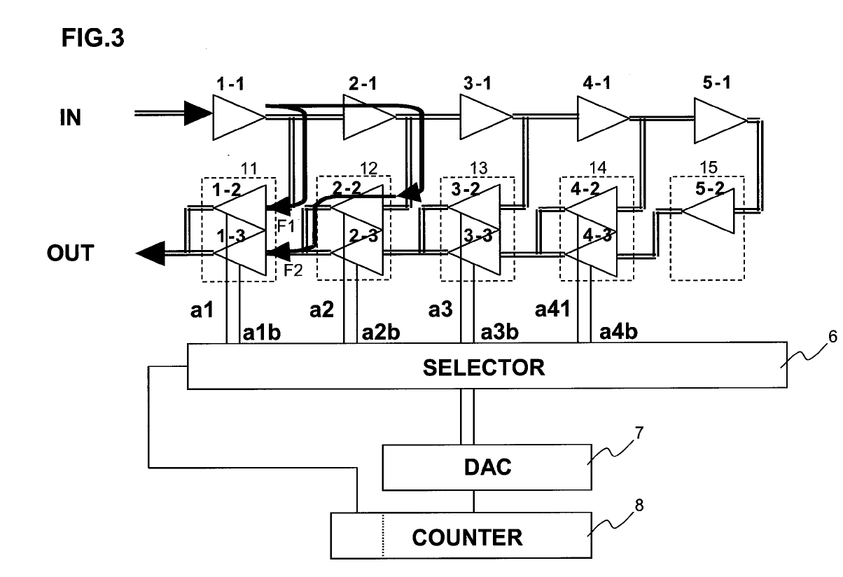

For example, in a case where a delay adjustment is carried out by the differential interpolator 11, the adjacent differential interpolator 12 outputs only the output of the differential amplifying circuit 2-1 with 100% synthesis, by way of example. As indicated by the delay paths represented by the bold lines in FIG. 3, a delayed signal F1 that is output from the differential delay circuit 1-1 and a delayed signal F2 obtained via the differential delay circuit 1-1, differential delay circuit 2-1 and differential amplifying circuit 2-2 are differentially input to the differential amplifying circuits 1-2 and 1-3, respectively, of the differential interpolator 11. In the differential amplifying circuits 1-2 and 1-3, the synthesizing ratio is adjusted in accordance with the levels of the bias voltages al, a1b, respectively, supplied thereto. A signal having a delay obtained by interpolating the delay difference between the delayed signals F1 and F2 based upon a1 and a1b is differentially output from the commonly connected output OUT of the differential amplifying circuits 1-2 and 1-3.

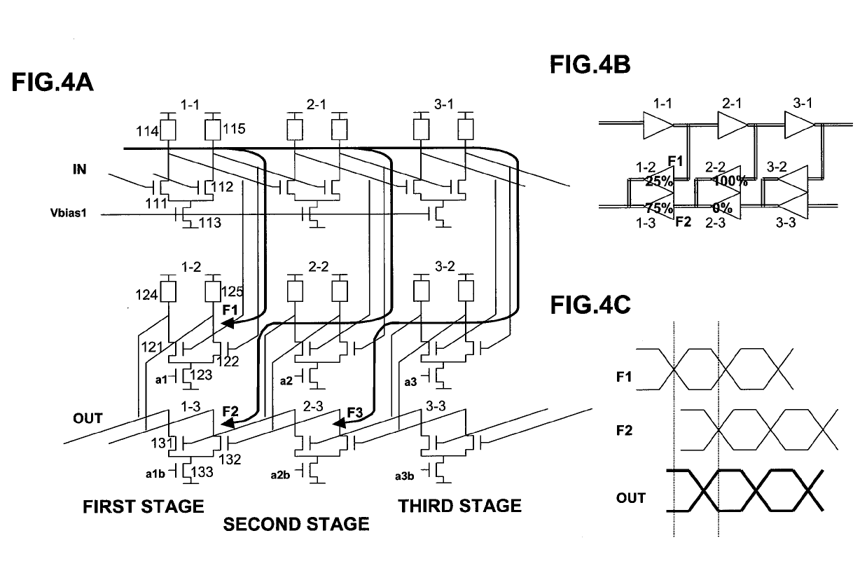

FIG. 4A illustrates the specific circuit configuration up to the third stage in FIG. 1. The differential delay circuit 1-1 includes N-channel MOS transistors 111 and 112 having sources coupled together, gates for receiving the input IN and drains connected to loads 114 and 115; and a current-source transistor 113, which is connected between ground and the coupled sources of the N-channel MOS transistors 111 and 112 and receives a bias voltage Vbias1 at its gate. The differential delay circuits 2-1 and 3-1 are similarly constructed. The gates of the transistors of the differential pair of differential delay circuit 2-1 are connected to the output pair of the differential delay circuit 1-1, and the gates of the transistors of the differential pair of differential delay circuit 3-1 are connected to the output pair of the differential delay circuit 2-1.

The differential amplifying circuits 1-2 and 1-3 constructing the differential interpolator 11 share loads 124 and 125. By controlling the bias voltages a1 and a1b, the synthesizing ratio of the signals F1 and F2 is adjusted.

If the bias voltages a1 and a1b of the differential amplifying circuits 1-2 and 1-3 are set with a ratio of 25%:75% and the bias voltages a2 and a2b of the differential amplifying circuits 2-2 and 2-3 are set with a ratio of 100%:0%, as illustrated in FIG. 4B, then the output OUT (the differential output of the differential interpolator 11) is adjusted to a delay obtained by synthesizing (interpolating) F1 (the output of differential delay circuit 1-1) and F2 (the signal obtained via the differential delay circuits 1-1, 2-1 and the differential amplifying circuit 2-2) with the ratio of 25%:75%, as illustrated in FIG. 4C. That is, the output OUT is set to an amount of delay obtained by internally dividing, with the ratio of 25%:75%=1:3, the difference between the amount of delay (see F1 in FIG. 4C) of the output of the differential interpolator in a case where the same delayed signal (differential signal) F1 has been supplied to the differential amplifying circuits 1-2 and 1-3 of the differential interpolator and the amount of delay (see F2 in FIG. 4C) of the output of the differential interpolator in a case where the same delayed signal (differential signal) F2 has been supplied to the differential amplifying circuits 1-2 and 1-3 of the differential interpolator.

In FIG. 4C, the waveform indicated by F1 illustrates the output waveform of the differential interpolator in a case where the signal F1 in FIGS. 4A and 4B has been supplied to the two differential amplifying circuits of the differential interpolator and the signals are synthesized with a ratio of 50%:50%. Alternatively, the waveform indicated at F1 illustrates the output waveform of the differential interpolator in a case where the signal F1 has been supplied to one differential amplifying circuit of the differential interpolator and has been output at 100%.

The waveform at F2 in FIG. 4C illustrates the output waveform of the differential interpolator in a case where the signal F2 in FIGS. 4A and 4B has been supplied to the two differential amplifying circuits of the differential interpolator and the signals are synthesized with a ratio of 50%:50%. Alternatively, the waveform indicated at F2 illustrates the output waveform of the differential interpolator in a case where the signal F2 has been supplied to one differential amplifying circuit of the differential interpolator and has been output at 100%.

The waveform indicated at OUT in FIG. 4C illustrates the output waveform of the differential interpolator in a case where the signals F1 and F2 of FIGS. 4A and 4B have been input to the two differential amplifying circuits of the differential interpolator and the signals have been synthesized with a ratio of 25%:75%. As illustrated in FIG. 4C, the end of the signal OUT is situated at a timing obtained by internally dividing respective timings of the edges of F1 and F2 with a ratio of 1:3.

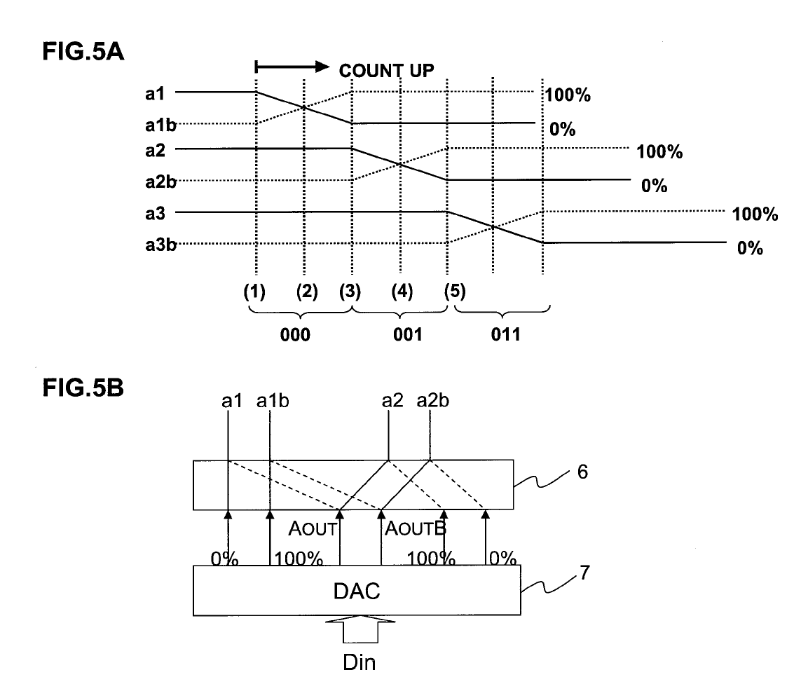

FIG. 5A is a diagram illustrating the relationship between the synthesizing of delays and bias levels. The ratio of the delays of the differential amplifying circuits 1-2 and 1-3 is controlled by the biases a1, a1b, and a1b becomes 100% (a1 is 0%). After the differential amplifying circuit 1-3 becomes 100%, the ratio of the delays of the differential amplifying circuits 2-2 and 2-3 is controlled by the biases a2, a2b. As a result, fine adjustment shifts to the side of the differential interpolator 12 comprising the differential amplifying circuits 2-2 and 2-3 and a further delay adjustment is possible.

The selector 6 of FIG. 1 is a circuit for performing changeover for outputting the level signal (analog voltage) from the DAC 7 to any one of the differential interpolators. In a case where one of the five differential interpolators is connected to the output analog voltage of the DAC 7, three upper order bits are input from the counter 8 to the selector 6 as the selection control signal, as mentioned earlier.

In states (1), (2) and (3) in FIG. 5A in which a1 and a1b are selected by the selector 6, the voltage of bias a1 from the DAC 7 decreases and the voltage of signal a1b the phase of which is reverse to that of a1 increases owing to the counting operation of the counter 8. When a1b becomes 100% and a1 becomes 0% after the voltages of a1, a1b cross [state (3)], these levels are maintained in a state in which a1, a1b are not selected [e.g., (3), (4), (5) . . . ].

FIG. 5B is a diagram illustrating an example of outputs of the DAC 7, the selector 6 and changeover of connection of the bias signals. At (1), (2) and (3) of FIG. 5A, the differential interpolator 11 is selected, the level signals (analog voltages AOUT and AOUTB) from the DAC 7 are supplied differentially as the bias voltages a1 and a1b (see the dashed lines in FIG. 5B) and voltages of 100% and 0% from the DAC 7 are supplied as a2 and a2b, respectively (see the dashed lines in FIG. 5B). At (3) of FIG. 5A when the level signals (analog voltages) supplied from the DAC 7 as a1 and a1b attain 0% and 100%, voltages of 0% and 100% from the DAC 7 are fixedly supplied as a1, a1b, respectively (see the solid lines in FIG. 5B). At (3), (4) and (5) of FIG. 5A, the differential interpolator 12 is selected and a changeover is made in such a manner that the level signals (analog voltages AOUT and AOUTB) from the DAC 7 are supplied differentially as the bias voltages a2 and a2b (see the solid lines in FIG. 5B).

It may be so arranged that the changeover to the fixed voltages of 0% and 100% is performed when the maximum value, etc., of the digital input to the DAC 7 is detected. The 0% voltage and 100% voltage from the DAC 7 correspond to reference voltages that decide the upper and lower limits of the DAC output voltage with respect to the digital input. In this example, the 100% voltage and 0% voltage are extracted from the DAC 7.

In FIG. 5A, 000, 001, 011, . . . shown below the states (1), (2), (3), (4) and (5) indicate the three upper order bits of the counter 8 that are supplied to the selector 6. Depending upon the upper order bits of the counter 8, the selector 6 selects at which of ai and aib (i=1 to N) the level signals, which are output from the DAC 7, are to be output. In states (1), (2) and (3), the differential interpolator 11 is selected by the three upper order bits “000” of the counter 8 and the level signals from the DAC 7 are supplied as a1 and a1b in conformity with the count-up operation of the counter 8, and a1 and a1b undergo a transition from 100% to 0% and from 0% to 100%, respectively. In states (3), (4) and (5), the differential interpolator 11 is selected by the three upper order bits “001” of the counter 8 and the level signals from the DAC 7 are supplied as a2 and a2b in conformity with the count-up operation of the counter 8, and a2 and a2b undergo a transition from 100% to 0% and from 0% to 100%, respectively. It should be noted that the bias voltage of 0% corresponds to, e.g., the lower limit of the output voltage of DAC 7 and is a voltage that turns off the current-source transistor of the differential amplifying circuit of the differential interpolator. The bias voltage of 100% corresponds to the upper limit of the output voltage of DAC 7. The DAC 7 receives the lower order bits of the counter 8 as a digital input and outputs voltages between 100% and 0% at a precision conforming to the number of bits in the digital input.

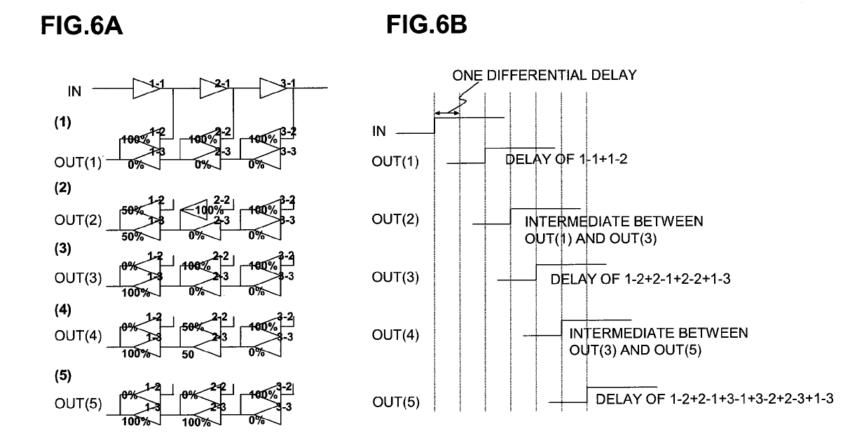

FIGS. 6A and 6B illustrate the delay adjustment circumstances at the times (1) to (5) in FIG. 5A. FIG. 6A illustrates the connections at the times (1) to (5) in FIG. 5A, and FIG. 6B shows the respective timing waveforms.

In the case of state (1) in FIG. 5A, a1, a2 and a3 are 100%, 100%, 100%, and a1b, a2b and a3b are 0%, 0%, and 0%. As shown at (1) in FIG. 6A, OUT(1) is obtained by delaying the input signal IN by the sum of the delay of differential delay circuit 1-1 and the delay (100%) of the differential amplifying circuit 1-2 (the delay is 1-1+1-2, or two delay unit) [see OUT(1) in FIG. 6B].

In the case of state (2) in FIG. 5A, a1, a2 and a3 are 50%, 100%, 100%, respectively and a1b, a2b and a3b are 50%, 0% and 0%, respectively. As shown at (2) in FIG. 6A, OUT(2) is obtained by subjecting the input signal IN to a delay (equivalent to three delay units) that is the result of synthesizing, with a ratio of 50%:50%, a signal obtained by delaying the input signal IN by the differential delay circuit 1-1 and differential amplifying circuit 1-2 (a delay of two units) and a signal obtained by the delaying the input signal IN by the differential delay circuit 1-1, differential delay circuit 2-1, differential amplifying circuit 2-2 and differential amplifying circuit 1-3 (a delay of four units) [see OUT(2) in FIG. 6B].

In the case of state (3) in FIG. 5A, a1, a2 and a3 are 0%, 100% and 100%, respectively and a1b, a2b and a3b are 100%, 0%, and 0%, respectively. As shown at (3) in FIG. 6A, OUT(3) is obtained by subjecting the input signal IN to a delay (equivalent to four delay units) by differential delay circuit 1-1, differential delay circuit 2-1, differential amplifying circuit 2-2 and differential amplifying circuit 1-3 [see OUT(3) in FIG. 6B].

In the case of state (4) in FIG. 5A, a1, a2 and a3 are 0%, 50%, and 100%, respectively and a1b, a2b and a3b are 100%, 50% and 0%, respectively. As shown at (4) in FIG. 6A, OUT(3) is obtained by subjecting the input signal IN to a delay (equivalent to five delay units) that is the result of synthesizing, with a ratio of 50%:50%, a signal obtained by delaying the input signal IN by the differential delay circuit 1-1, differential delay circuit 2-1 and differential amplifying circuit 2-2 (a delay of three units) and a signal obtained by the delaying the input signal IN by the differential delay circuit 1-1, differential delay circuit 2-1, differential delay circuit 3-1, differential amplifying circuit 3-2 and differential amplifying circuit 2-3 (a delay of five units), and further adding on the delay of the differential amplifying circuit 1-3 [see OUT(4) in FIG. 6B].

In the case of state (5) in FIG. 5A, a1, a2 and a3 are 0%, 0% and 100%, respectively and a1b, a2b and a3b are 100%, 100% and 0%, respectively. As shown at (5) in FIG. 6A, OUT(5) is obtained by subjecting the input signal IN to a delay (equivalent to six delay units) by differential delay circuit 1-1, differential delay circuit 2-1, differential amplifying circuit 3-2, differential amplifying circuit 2-3 and differential amplifying circuit 1-3 [see OUT(5) in FIG. 6B].

OUT(2) is intermediate OUT(1) delayed by two delay units and OUT(3) delayed by four delay units, and OUT(4) is intermediate OUT(3) delayed by four delay units and OUT(6) delayed by six delay units.

Thus, in accordance with this exemplary embodiment, it will be understood that delay can be shifted over a broad adjustment range while the delay of the differential delay circuits (1-1, 2-1, 3-1) is held fixed.

Another exemplary embodiment of the present invention will be described next. In a case where a delay is produced by waveform synthesis by the differential amplifying circuits 1-2 and 1-3 of the differential interpolator 11 in FIG. 1, it is necessary that the differential delay circuit 2-1 and differential amplifying circuit 2-2 operate but the others are not required to operate.

In a case where the period of the clock cycle is short, the range of delay handled by a DLL is small. In such case adjustment is possible with just the first and second stages. Accordingly, it may be so arranged that consumption of power is suppressed by halting the current in differential amplifying circuits that have no bearing upon the delay adjustment.

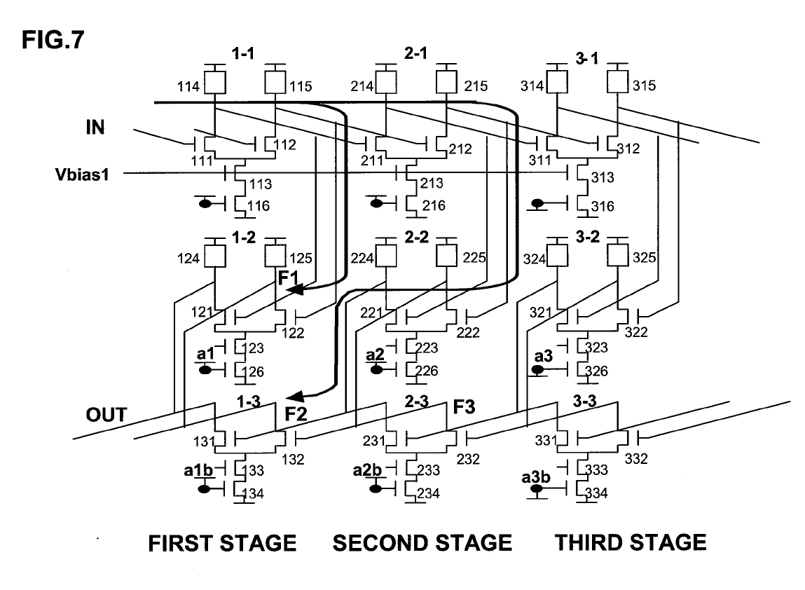

As illustrated in FIG. 7, switches (116, 126, 136, 216, 226, 236, 316, 326, 336) are provided between ground and the current sources (113, 123, 133, 213, 223, 233, 313, 323, 333) of the differential delay circuits and differential amplifying circuits of the interpolators (1-1, 1-2, 1-3, 2-1, 2-2, 2-3, 3-1, 3-2, 3-3). As shown in FIG. 7, it may be so arranged that in a case where the differential amplifying circuits 3-2 and 3-3 of the interpolator corresponding to the differential delay circuit 3-1 are halted, the gate voltages of the switches (NMOS transistors) 316, 326 and 334 of the differential delay circuit 3-1 and differential amplifying circuits 3-2 and 3-3 are placed at ground potential to thereby turn them off, as a result of which the flow of current is halted.

On the other hand, the gates of the switches (NMOS transistors) 116, 126 and 134 of the differential delay circuit 1-1 and differential amplifying circuits 1-2 and 1-3 and the gates of the switches 216, 226 and 234 of the differential delay circuit 2-1 and differential amplifying circuits 2-2 and 2-3 are placed at power-supply potential to thereby turn on the switches. It may be so arranged that which number of stages are halted is controlled using the count output of the counter, by way of example.

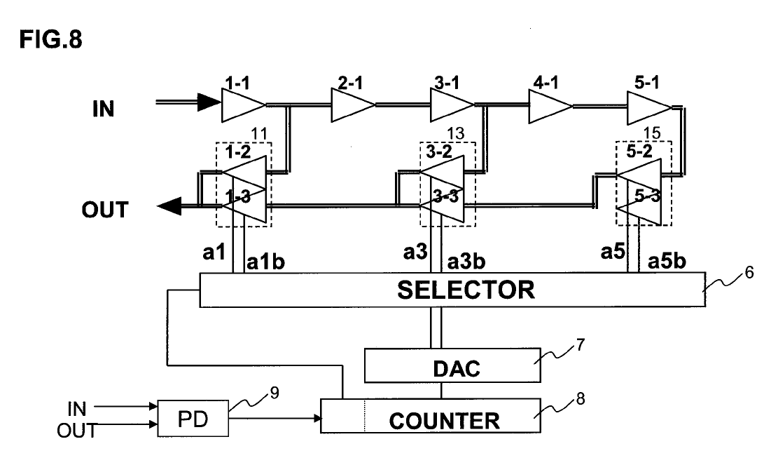

FIG. 8 is a diagram illustrating the configuration of another exemplary embodiment of the present invention. In this exemplary embodiment, an arrangement may be adopted in which the number of differential interpolators is reduced, as shown in FIG. 8. In the example illustrated in FIG. 8, the differential interpolators 11, 13 and 15 of three stages are provided with respect to the differential delay circuits (1-1, 2-1, 3-1, 4-1, 5-1) of the five stages, so that a differential interpolator is provided for every two differential delay circuits. The differential outputs of the differential delay circuit 1-1 and differential interpolator 13 are supplied to the differential amplifying circuits 1-2 and 1-3 of the differential interpolator 11. The differential outputs of the differential delay circuit 3-1 and differential interpolator 15 are supplied to the differential amplifying circuits 3-2 and 3-3 of the differential interpolator 13.

The arrangement of FIG. 8 corresponds to one in which the differential delay circuits (1-1, 2-1, 3-1, 4-1, 5-1) of five stages have been divided into three groups {1-1}, {2-1, 3-1}, and {4-1, 5-1} in correspondence with the differential interpolators 11, 13 and 15 of three stages. If the adjustment range of the differential interpolators is broadened, it is possible to reduce the number of interpolators as in the arrangement of this example.

In accordance with the foregoing embodiment, the adjustment range from short delay to long delay is broad, namely from a delay equivalent to two differential amplifying circuits to a delay equivalent to N×2 differential amplifying circuits.

In accordance with the foregoing embodiment, the delays of the differential amplifying circuits per se are not changed. Accordingly, the operating points of the differential amplifying circuits are the same, the slew rate of the signal of the differential amplifying circuits does not slow down and resistance to noise does not decline.

It should be noted that the arrangement having the differential delay circuits and differential interpolators in FIG. 1 has been described as one example. However, it goes without saying that each delay circuit may be a single-ended-transmission delay circuit and each interpolator may be an interpolator that synthesizes the delays of the single-ended output of the delay circuit and the output of the interpolator of the preceding stage.

The present invention is used in all systems synchronized to an external clock by an internal clock. For example, it is possible to use the present invention in DRAMs from a DDR1 onward and in controllers that use these DRAMs.

Though the present invention has been described in accordance with the foregoing embodiments, the invention is not limited to these embodiments and it goes without saying that the invention covers various modifications and changes that would be obvious to those skilled in the art within the scope of the claims.

What is claimed is:

1. A semiconductor device comprising:
a delay line including a plurality of stages of delay circuits in which a signal received by a first stage delay circuit propagates in a direction of from a preceding stage delay circuit to a succeeding stage delay circuit; and
a plurality of stages of interpolators arranged in a manner that a signal propagates in a direction opposite to the direction of propagation of the signal in the delay line,
at least one interpolator among the plurality of stages of interpolators receiving a signal from the delay circuit of a corresponding stage and a signal produced by the interpolator of a succeeding stage and performing waveform synthesis of the signals received with a ratio specified by a control signal supplied thereto to supply the synthesized signal to a preceding stage, and
a delay-adjusted signal being produced from an interpolator situated at a first stage.

2. The semiconductor device according to claim 1, wherein an interpolator situated at a last stage among the plurality of stages of interpolators receives a signal from the delay circuit of the stage corresponding to the interpolator at the last stage.

3. The semiconductor device according to claim 1, wherein the number of stages of the interpolators is equal to or greater than the number of stages of the delay circuits in the delay line.

4. The semiconductor device according to claim 1, wherein the delay circuit includes a differential delay circuit having a differential-input and a differential-output.

5. The semiconductor device according to claim 1, wherein at least the one interpolator among the plurality of stages of interpolators includes
first and second differential amplifying circuit having in common a load-element pair, having respective output pairs connected in common to the common load element pair, with a differential output signal being output from connection nodes of the output pairs and the common load-element pair, wherein
the first differential amplifying circuit differentially receives an output signal of the delay circuit of a corresponding stage,
the second differential amplifying circuit differentially receives an output signal of the interpolator of a succeeding stage, and
the first and second differential amplifying circuits respectively vary driving currents based upon control signals respectively supplied thereto to vary the delay of a synthesized output signal.

6. The semiconductor device according to claim 1, wherein the interpolator of the last stage includes
a first differential amplifying circuit differentially receiving an output signal from the delay circuit of the stage corresponding to the interpolator of the last stage.

7. The semiconductor device according to claim 5, wherein the first differential amplifying circuit includes:
a first differential pair having an output pair connected to the common load element pair; and
a first current source that supplies a driving current to the first differential pair, wherein
the second differential pair includes:
a second differential pair having an output pair connected to the common load element pair; and
a second current source that supplies a driving current to the second differential pair, and wherein
a first bias voltage for controlling the current value of the first current source is supplied to the first current source as the control signal, and
a second bias voltage for controlling the current value of the second current source is supplied to the second current source as the control signal.

8. The semiconductor device according to claim 5, wherein the first differential amplifying circuit includes:
a first differential pair having an output pair connected to the common load element pair;
a first current source that supplies a driving current to the first differential pair;
a first switch that turns a current path of the first current source on and off, wherein
the second differential pair includes:
a second differential pair having an output pair connected to the common load element pair;
a second current source that supplies a driving current to the second differential pair;
a second switch that turns a current path of the second current source on and off, and wherein
a first bias voltage for controlling the current value of the first current source is supplied to the first current source as the control signal, and
a second bias voltage for controlling the current value of the second current source is supplied to the second current source as the control signal.

9. The semiconductor device according to claim 4, wherein the differential delay circuit includes:
a differential pair that differentially receives a signal from a preceding stage at an input pair and differentially outputs a signal from an output pair;
a load element pair connected to the output pair; and
a current source that supplies a driving current to the differential pair.

10. The semiconductor device according to claim 4, wherein the differential delay circuit includes:
a differential pair that differentially receives a signal from the preceding stage differentially at an input pair and outputs a signal differentially from an output pair;
a load element pair connected to the output pair;
a current source that supplies a driving current to the differential pair; and
a switch that turns a current path of the current source on and off.

11. The semiconductor device according to claim 1, further comprising:
a phase detector that detects a phase difference between an output signal from the interpolator of the last stage and an input signal supplied to the a first stage delay circuit of the delay line;
a counter that receives an output of the phase detector as an input and counts up or down in accordance with phase lag or phase lead;
a digital-to-analog converter that receives a bit signal of a first bit field of a count output from the counter as a digital input and outputs an analog voltage; and
a selector that selects any interpolator of the plurality of stages based upon a bit signal of a second bit field of the count output from the counter, supplies the analog voltage from the digital-to-analog converter to the selected interpolator as the control signal, and supplies other interpolators with previously prepared analog voltages as the control signal.

12. The semiconductor device according to claim 11, wherein, when the selector selects one interpolator and supplies the output voltage of the digital-to-analog converter as the control signal of the one interpolator selected, the selector supplies the previously prepared analog voltages as the control signal in order that one of either the output of the delay circuit or output of the interpolator of the preceding stage is synthesized into a waveform with a ratio of 100%.

13. The semiconductor device according to claim 1, wherein the delay line includes N (where N is a predetermined positive integer) stages of differential delay circuits, and
there are provided N stages of differential interpolators, wherein
a differential interpolator of an Mth (where M<N holds) stage receives an output signal of a differential delay circuit of the Mth stage and an output signal of a differential interpolator of an (M+1)th stage,
a differential interpolator of an Nth stage receives an output signal of a differential delay circuit of the Nth stage as an input and synthesizes the received signal into a signal with a synthesizing ratio of 100%,
a differential interpolator selected from among differential interpolators from first to (N−1)th stages performs waveform synthesis of two input signals with a range of as from 0% to 100% in accordance with a control signal supplied thereto, and
a delay-adjusted output signal is output from the differential interpolator of the first stage.

14. The semiconductor device circuit according to claim 13, wherein differential delay circuits and differential interpolators from the (M+2)th stage onward are set to an inactive state during delay adjustment by the differential interpolator of the Mth stage.

15. The semiconductor device according to claim 1, wherein the delay line includes N (where N is a predetermined positive integer) stages of differential delay circuits, and
there are provided L (where N>L>1 holds) stages of differential interpolators, wherein
the N stages of differential delay circuits are divided into L-number of groups,
an output of one differential delay circuit among differential delay circuits of an Mth (where M<N holds) group and an output of a differential interpolator of an (M+1)th stage are supplied to a differential interpolator of an Mth stage,
a differential interpolator of an Lth stage receives an output of one differential delay circuit among differential delay circuits of an Lth group as an input and synthesizes the received signal into a waveform with a synthesizing ratio of 100%, and
a delay-adjusted output signal is output from the differential interpolator of the first stage.

16. The semiconductor device according to claim 1, wherein the delay line and the interpolators constitute a delay locked loop.

17. A method of adjusting a delay in a semiconductor device comprising a delay line including a plurality of stages of delay circuits and a plurality of stages of interpolators, the method comprising:
a signal received by a first stage delay circuit of the delay line propagating in a direction of from a preceding stage delay circuit to a succeeding stage delay circuit in the delay line, while a signal propagating through the plurality of stages of interpolators in a direction opposite to the direction of propagation of the signal in the delay line;
at least one interpolator among the plurality of stages of interpolators receiving a signal from the delay circuit of a corresponding stage and a signal produced by the interpolator of a succeeding stage, performing waveform synthesis of the signals received with a ratio specified by a control signal supplied thereto, and supplying the synthesized signal to a preceding stage; and
producing, by an interpolator situated at a first stage, a delay-adjusted signal.

18. The method according to claim 17, further comprising
an interpolator situated at a last stage among the plurality of stages of interpolators receiving a signal from the delay circuit of the stage corresponding to the interpolator at the last stage.
